(19) United States
(12) Patent Application Publication
(10) Pub. No.: US 2007/0029608 A1
(43) Pub. Date: Feb. 8, 2007

(54) Offset spacers for CMOS transistors

(75) Inventor: Chien-Chao Huang, Hsin-Chu (TW)

Correspondence Address: SLATER & MATSIL, L.L.P., 17950 PRESTON ROAD, SUITE 1000, DALLAS, TX, 75252, US

(73) Assignee: Taiwan Semiconductor Manufacturing Company, Ltd.

(21) Appl. No.: 11/199,486

(22) Filed: Aug. 8, 2005

(51) Int. Cl. H01L 29/772; H01L 21/336; H01L 21/8238

(52) U.S. Cl. 257/327; 438/301; 438/305

(57) ABSTRACT

An offset spacer for CMOS transistors and a method of manufacture is provided. A gate electrode is formed on a substrate, and an offset mask layer is formed over the surface of the gate electrode and the substrate. The offset mask may be formed of an oxide layer and acts as a mask during implanting, such as pocket implants and lightly-doped drain implants. A second implant spacer may be formed on top of the offset mask layer adjacent the gate electrode, and another implant process may be performed to form deeply-doped drain regions.

### TECHNICAL FIELD

The present invention relates generally to semiconductor devices, and more particularly, to offset spacers for complementary metal oxide-semiconductor transistors.

### BACKGROUND

Complementary metal-oxide-semiconductor (CMOS) technology is the dominant semiconductor technology used for the manufacture of ultra-large scale integrated (ULSI) circuits today. Size reduction of the semiconductor structures has provided significant improvement in the speed, performance, circuit density, and cost per unit function of semiconductor chips over the past few decades. Significant challenges, however, are faced as the sizes of CMOS devices continue to decrease.

For example, as the length of the gate electrode of a CMOS transistor is reduced, particularly with gate lengths of less than about 30 nm, the source and drain regions increasingly interact with the channel and gain influence on the channel potential and the gate dielectric. Consequently, a transistor with a short gate length suffers from problems related to the inability of the gate electrode to substantially control the on and off states of the channel. Phenomena such as reduced gate control associated with transistors with short channel lengths are termed short-channel effects.

One method of reducing the influence of the source and drain on the channel and the gate dielectric is to utilize offset spacers to the control implanting process when forming the source/drain regions. Conventional offset spacers are typically formed by depositing one or more dielectric layers over the gate electrode. An etching process is used to form spacers alongside the gate electrode. In such a process, the uniformity of the resulting offset spacers is dependent upon the uniformity of the etching process, which is difficult to control. Furthermore, this method of forming offset spacers is difficult to control the width of the offset spacer and to scale the width of the offset spacer as the size of the gate electrode changes due to the inability to accurately control the etching process.

As a result, the conventional offset spacer is most applicable when the desired offset is greater than 100 Å where the design tolerances are looser. In smaller designs, e.g., designs in which an offset spacer is less than about 100 Å, the conventional offset spacer is difficult to control. Accordingly, there is a need for an offset spacer that allows easier scaling and width control.

### SUMMARY OF THE INVENTION

These and other problems are generally reduced, solved or circumvented, and technical advantages are generally achieved, by embodiments of the present invention, which provides an offset spacer for complementary metal oxide semiconductor transistors.

In an embodiment of the present invention, an offset spacer for CMOS transistors and a method of manufacture is provided. The offset spacer comprises an offset mask layer formed over a gate electrode. Preferably, the offset mask is formed of a dielectric material, such as an oxide, having a substantially uniform thickness. The offset mask layer may be used to perform a first implant process to form lightly-doped drains and/or pocket implants. Because the offset mask layer adjacent the gate electrode is not etched, the thickness and uniformity is easier to control than conventional spacers in which a layer is deposited and etched.

In another embodiment, one or more additional spacers and implant processes may be formed on the offset mask layer adjacent the gate electrode to form deeply-doped drains.

Embodiments of the present invention may be used to form PMOS transistor and/or NMOS transistors for memory devices, core devices, I/O devices, or the like.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1-6 are cross-sectional views of a wafer after various process steps are performed in accordance with one embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

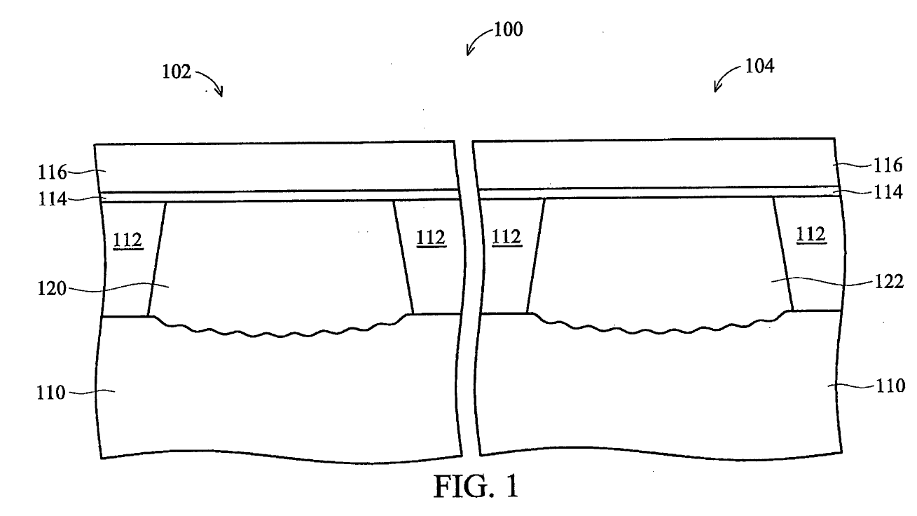

FIGS. 1-6 illustrate an embodiment for fabricating an NMOS and a PMOS transistor using an offset spacer in accordance with an embodiment of the present invention. Embodiments of the present invention may be used in a variety of circuits. For example, embodiments of the present invention may be useful in I/O devices, core devices, memory circuits, system-on-chip (SoC) devices, other integrated circuits, and the like. Furthermore, embodiments of the present invention may be particularly useful in sub-65 nm designs where short-channel effects may be more troublesome.

Referring first to FIG. 1, a wafer 100 is shown comprising a substrate 110 having an NMOS region 102 and a PMOS region 104 in accordance with an embodiment of the present invention. In an embodiment, the substrate 110 comprises a P-type bulk silicon substrate having a P-well 120 formed in the NMOS region 102 and an N-well 122 formed in the PMOS region 104, in which NMOS devices and PMOS devices may be formed, respectively. Other materials, such as germanium, silicon-germanium alloy, or the like, could alternatively be used for the substrate 110. The substrate 110 may also be an active layer of a semiconductor-on-insulator (SOI) substrate or a multi-layered structure such as a silicon-germanium layer formed on a bulk silicon layer.

The P-wells 120 may formed by implantation with, for example, boron ions at a dose of about 1e12 to about 1e14 atoms/cm2 and at an energy of about 30 to about 300 KeV. Other P-type dopants, such as aluminum, gallium, indium, or the like, may also be used. The N-well 122 may be formed by implantation with, for example, phosphorous ions at a dose of about 1e12 to about 1e14 atoms/cm2 and at an energy of about 100 to about 500 KeV. Other N-type dopants, such as nitrogen, arsenic, antimony, or the like, may also be used.

Shallow-trench isolations (STIs) 112, or some other isolation structures such as field oxide regions, may be formed in the substrate 110 to isolate active areas on the substrate. The STIs 112 may be formed by etching trenches in the substrate and filling the trenches with a dielectric material, such as silicon dioxide, a high-density plasma (HDP) oxide, or the like, as known in the art.

A dielectric layer 114 and a conductive layer 116 may be formed over the substrate 110. The dielectric layer 114 comprises a dielectric material, such as silicon dioxide, silicon oxynitride, silicon nitride, a nitrogen-containing oxide, a high-K metal oxide, a combination thereof, or the like. A silicon dioxide dielectric layer may be formed, for example, by an oxidation process, such as wet or dry thermal oxidation, or by CVD oxide, such as LPCVD (Low Pressure Chemical Vapor Deposition) oxide, PECVD (Plasma Enhanced Chemical Vapor Deposition) oxide or ALCVD (Atomic Layer Chemical Vapor Deposition) oxide. In the preferred embodiment, the dielectric layer 114 is about 10 Å to about 40 Å in thickness.

The conductive layer 116 comprises a conductive material, such as a metal (e.g., tantalum, titanium, molybdenum, tungsten, platinum, aluminum, haffium, ruthenium), a metal silicide (e.g., titanium silicide, cobalt silicide, nickel silicide, tantalum silicide), a metal nitride (e.g., titanium nitride, tantalum nitride), doped poly-crystalline silicon, other conductive materials, or a combination thereof. In one example, amorphous silicon is deposited and re-crystallized to create poly-crystalline silicon (polysilicon). The polysilicon layer may be formed by depositing doped or undoped polysilicon by low-pressure chemical vapor deposition (LPCVD) or Rapid Thermal Chemical Vapor Deposition (RTCVD) to a thickness in the range of about 200 Å to about 2000 Å, but more preferably about 1000 Å. It should be noted that the conductive layer 116 may be doped separately for the NMOS region 102 and the PMOS region 104. Masking layers (not shown) may be selectively used to protect the PMOS region 104 while implanting the NMOS region 102 and to protect the NMOS region 102 while implanting the PMOS region 104.

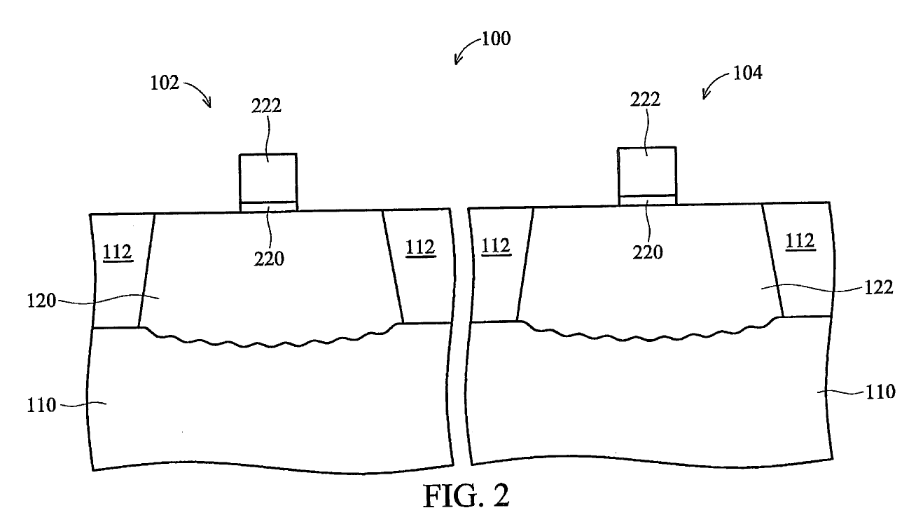

FIG. 2 illustrates the wafer 100 of FIG. 1 after the dielectric layer 114 and the conductive layer 116 of FIG. 1 have been patterned to form a gate dielectric 220 and gate electrode 222, respectively, in accordance with an embodiment of the present invention. The gate dielectric 220 and the gate electrode 222 may be patterned by photolithography techniques as are known in the art. Generally, photolithography involves depositing a photoresist material, which is then masked, exposed, and developed. After the photoresist mask is patterned, an anisotropic etching process may be performed to remove unwanted portions of the dielectric layer 114 (FIG. 1) and the conductive layer 116 (FIG. 1) to form the gate dielectric 220 and the gate electrode 222, respectively, as illustrated in FIG. 2.

The gate length of the gate electrode 222 may be varied for a particular application. However, it has been found that embodiments of the present invention are particularly useful in designs utilizing a gate length of about 25 nm or less where the short-channel effects may be more troublesome.

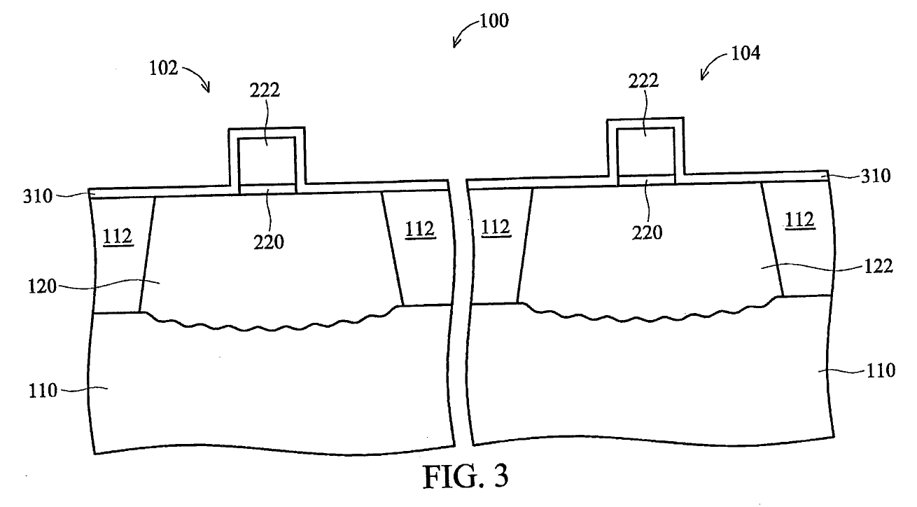

FIG. 3 illustrates the wafer 100 of FIG. 2 after an offset masking layer 310 has been formed in accordance with an embodiment of the present invention. The offset masking layer 310 is preferably a substantially conformal oxide layer. In an embodiment, the offset masking layer 310 comprises an oxide, such as silicon dioxide layer formed by atomic-layer deposition (ALD) techniques known in the art. Other methods, such as chemical vapor deposition (CVD), low-pressure CVD (LPCVD), or the like, and other materials, such as silicon oxynitride, silicon, a combination thereof, or the like, may also be used. In the preferred embodiment, the offset masking layer 310 is about 20 Å to about 100 Å in thickness, but more preferably larger than about 20 Å in thickness. It should be noted, however, that the thickness of the offset masking layer 310 defines the width of the spacer used to form pocket implants and the source/drain regions in subsequent processing steps.

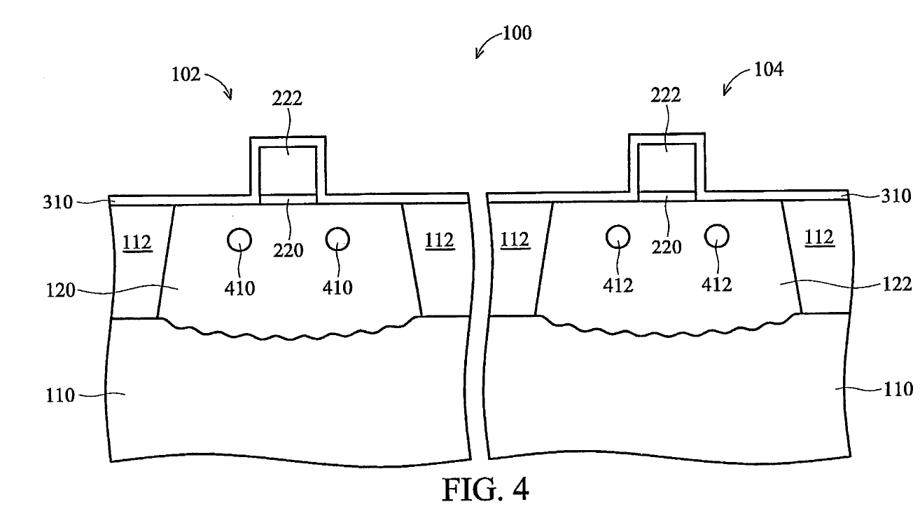

FIG. 4 illustrates the wafer 100 of FIG. 3 after optional pocket implant regions 410 and 412 have been formed in accordance with an embodiment of the present invention. In the embodiment, the pocket implant regions 410 in the NMOS region 102 may be formed by implanting P-type impurities in the substrate 110 as illustrated in FIG. 4. For example, boron ions at a dose of about 1e13 to about 1e14 atoms/cm² and at an energy of about 3 to about 10 KeV may be implanted to form the pocket implant regions 412. Alternatively, the implanting process may use other P-type impurities, such as boron difluoride, aluminum, gallium, indium, or the like.

The pocket implant regions 412 in the PMOS region 104 may be formed by implanting N-type impurities in the substrate 110. For example, arsenic ions at a dose of about 1e13 to about 1e14 atoms/cm² and at an energy of about 30 to about 100 KeV may be implanted to form the pocket implant regions 412. Alternatively, the implanting process may use other N-type impurities, such as phosphorous, antimony, or the like.

It should be noted that the gate electrode 222 and the offset masking layer 310 adjacent the gate electrode 222 act as an implant mask for the ion implant process to form the pocket implant regions 410 and 412. One skilled in the art will appreciate that the depth and the lateral dimensions of the pocket implant regions 410 and 412 may be controlled by the implant angle (e.g., implanting at an angle normal, oblique, or the like to the surface of the substrate 110), the dose, and the energy level of the implant. Furthermore, additional masks (not shown) may be used to control the width of the pocket implant regions and the distance the pocket implant regions 410 and 412 extend away from the gate electrode 222. Thus, the dimensions and the density of the pocket implant regions 410 and 412 may be customized for a particular application and for a particular gate length, and may be customized to extend below the gate electrode 222. An anneal process may be performed after the pocket implant regions 410 and 412 have been formed to activate and laterally diffuse the implanted ions.

It should be noted that the pocket implant regions 410 and 412 are shown to be similar for both the NMOS region 102 and the PMOS region 104 for illustrative purposes only. The shape and/or position of the pocket implant regions 410 in the NMOS region 102 may be the same or different than the pocket implant regions 412 in the PMOS region 104. Furthermore, it should be noted that only one of the pocket implant regions 410 and 412 may be used.

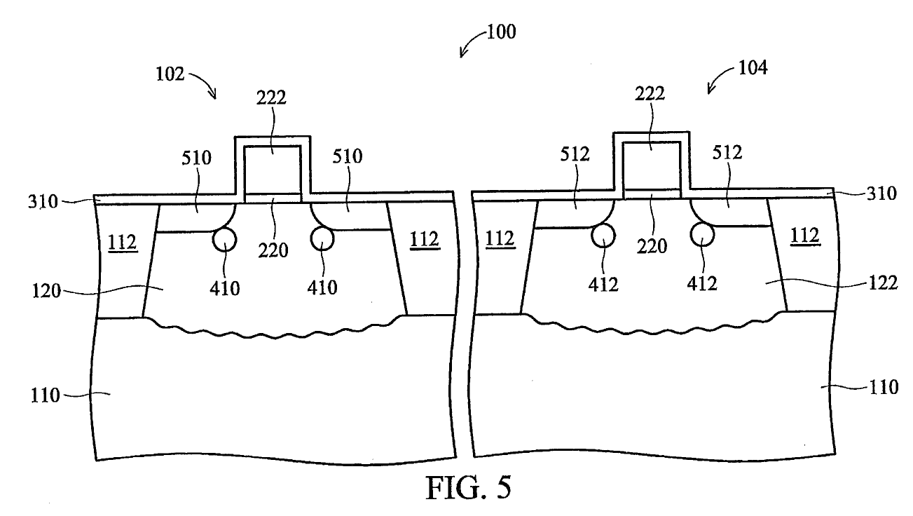

FIG. 5 illustrates the wafer 100 of FIG. 4 after a first N-type implant region 510 and a first P-type implant region 512 have been formed in accordance with an embodiment of the present invention. The first N-type implant region 510 forms lightly-doped drain (LDD) regions for an NMOS transistor in the NMOS region 102. In a preferred embodiment, a mask is formed and patterned over the PMOS region 104 such that the N-type dopants will not be implanted in the PMOS region 104. The first N-type implant region 510 may be doped with, for example, an N-type dopant, such as phosphorous ions at a dose of about 5e14 to about 2e15 atoms/cm² and at an energy of about 2 to about 5 KeV. Alternatively, the first N-type implant region 510 may be doped with other N-type dopants such as arsenic, nitrogen, antimony, or the like. The mask may be removed after forming the first N-type implant region 510.

In an embodiment, the implants performed to create the LDD regions (e.g., the first N-type implant region 510 and the second P-type implant region 512) at a 90° angle to the surface of the substrate. The ions may pass through horizontal portions of the offset masking layer 310, but may remain in vertical sections of the offset masking layer 310 adjacent the gate electrode. In this manner, the LDD regions are separated from the gate electrode, thereby reducing the short-channel effects.

The first P-type implant region 512 forms the LDD regions for a PMOS transistor in the PMOS region 104. In an embodiment, a mask is formed and patterned over the NMOS region 102 such that the P-type dopants will not be implanted in the NMOS region 102. The first P-type implant region 512 may be doped with, for example, a P-type dopant, such as boron ions at a dose of about 5e14 to about 2e15 atoms/cm² and at an energy of about 0.3 to about 1 KeV. Alternatively, the first P-type implant region 512 may be doped with other P-type dopants such as aluminum, gallium, indium, or the like. The mask may be removed after forming the first P-type implant region 512.

It should be noted that the masks used to form the LDDs and the pocket implants may be the same mask or different masks for the NMOS region 102 and the PMOS region 104. It should also be noted that the offset mask layer 310 may be lightly doped from the implant procedures used to form one or more of the pocket implant regions 410, 412 and/or one or more of the implant regions 510, 512.

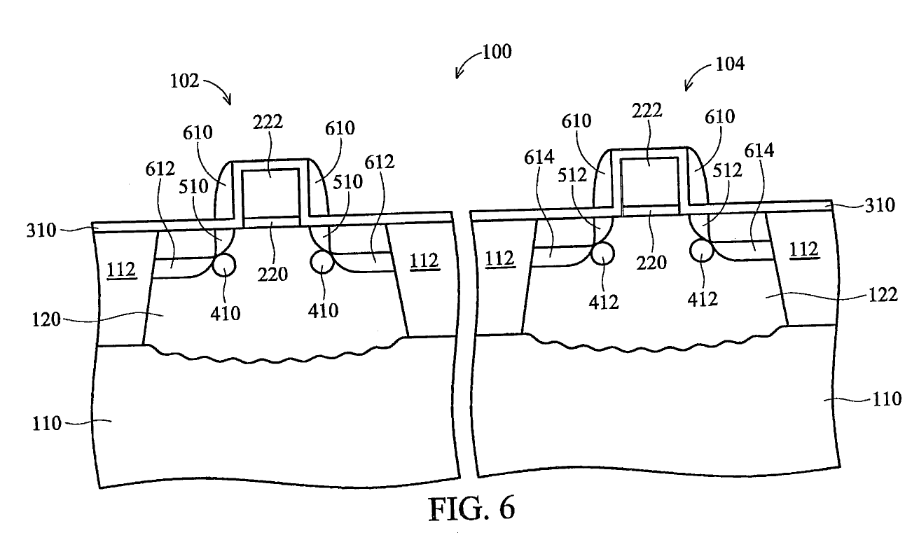

FIG. 6 illustrates the wafer 100 of FIG. 5 after first implant spacers 610 have been formed and second N-type implant regions 612 and second P-type implant regions 614 have been formed in accordance with an embodiment of the present invention. The first implant spacers 610, which form implant masks for a second ion implant in the source/drain regions, preferably comprise a nitrogen-containing layer, such as silicon nitride (Si₃N₄), silicon oxynitride SiOₓN_{y}, silicon oxime SiOₓN_{y}:H_{z}, a combination thereof, or the like; or comprise a carbon-containing layer, such as silicon carbide (SiC). In a preferred embodiment, the first implant spacers 610 are formed from a layer comprising Si₃N₄ that has been formed using chemical vapor deposition (CVD) techniques using silane and ammonia (NH₃) as precursor gases. Other materials and processes may be used. However, it should be noted that it is preferred that a high-etch selectivity exists between the material used to form the offset masking layer 310 and the first implant spacers 610.

The first implant spacers 610 may be patterned by performing an isotropic or anisotropic etch process, such as an isotropic etch process using a solution of phosphoric acid (H₃PO₄) wherein the offset masking layer 310 acts as an etch-stop. Because the thickness of the layer of Si₃N₄ (or other material) is greater in the regions adjacent to the gate electrode 222, the isotropic etch removes the Si₃N₄ material except for that material adjacent the gate electrode 222, thereby forming the first implant spacers 610 as illustrated in FIG. 6.

It should be noted that masks may be used to protect the PMOS region 104 while implanting N-type dopants in the NMOS region 102 and to protect the NMOS region 102 while implanting P-type dopants in the PMOS region 104.

It should also be noted that different spacers and doping profiles may be used, and that different doping profiles may be used for the NMOS and PMOS transistors. For example, additional spacers and implants may be used to form the source/drain regions for the NMOS transistor and/or the PMOS transistors. As another example, the spacers used for the NMOS transistors may be thinner or thicker than the spacers used for PMOS transistors. Furthermore, fewer implants may be used for one or both of the NMOS and PMOS transistors.

Thereafter, standard processing techniques may be used to complete fabrication of the semiconductor device. For example, the source/drain regions and the gate electrode may be silicided, inter-layer dielectrics may be formed, contacts and vias may be formed, metal lines may be fabricated, and the like.

As one of ordinary skill in the art will appreciate, embodiments of the present invention provide several advantages. For example, conventional offset spacers are typically formed by multiple deposition and etching steps. The embodiment of the present invention discussed above utilizes a single offset masking layer that does not need to be etched, thereby eliminating an etching step, and possibly a deposition and cleaning step, thereby reducing processing time and costs.

Furthermore, the use of the offset masking layer of an embodiment of the present invention may be more accurately controlled. In particular, the offset masking layer of the present invention does not need to be etched as in prior art methods. Because the offset masking layer does not need to be etched, the width of the offset mask may be more easily controlled.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming a semiconductor device, the method comprising:
providing a substrate;
forming a gate electrode over the substrate;
forming an offset mask layer over the gate electrode and the substrate, the offset mask layer being in contact with the substrate; and
forming source/drain regions in the substrate on opposing sides of the gate electrode, the forming being performed at least in part by implanting ions through the offset mask layer in the source/drain regions.

2. The method of claim 1, wherein the gate electrode has a gate length of less than 25 nm.

3. The method of claim 1, further comprising forming implant spacers on the offset mask layer adjacent the gate electrode and implanting ions in the source/drain regions using the implant spacers as implant masks.

4. The method of claim 3, wherein the implant spacers comprise a nitrogen-containing material or a carbon-containing material.

5. The method of claim 1, wherein the offset mask layer comprises an oxide.

6. The method of claim 1, wherein the offset mask layer is less than about 10 nm in thickness.

7. The method of claim 1, further comprising forming pocket implant regions in the source/drain regions after the forming the offset mask layer.

8. A method of forming a semiconductor device, the method comprising:
providing a substrate;
forming a gate electrode over the substrate;
forming an offset mask layer over the gate electrode and the substrate; and
implanting ions in the substrate in the source/drain regions on opposing sides of the gate electrode, wherein ions are implanted in at least a portion of the offset mask layer adjacent the gate electrode.

9. The method of claim 8, further comprising forming implant spacers on the offset mask layer adjacent the gate electrode and implanting ions in the source/drain regions using the implant spacers as implant masks.

10. The method of claim 9, wherein the implant spacers comprise a nitrogen-containing material or a carbon-containing material.

11. The method of claim 8, wherein the offset mask layer comprises an oxide.

12. The method of claim 8, wherein the offset mask layer is less than about 10 nm in thickness.

13. The method of claim 8, further comprising forming pocket implant regions in the source/drain regions after the forming the offset mask layer.

14. A semiconductor device comprising:
a substrate;
a gate electrode formed on the substrate;
source/drain regions formed in the substrate on opposing sides of the gate electrode; and
an offset mask layer formed over the gate electrode and the substrate, the offset mask layer having ions implanted in at least a portion alongside the gate electrode.

15. The semiconductor device of claim 14, wherein the gate electrode has a length of less than 25 nm.

16. The semiconductor device of claim 14, further comprising implant spacers on the offset mask layer adjacent the gate electrode.

17. The semiconductor device of claim 16, wherein the implant spacers comprise a nitrogen-containing material.

18. The semiconductor device of claim 16, wherein the implant spacers comprise a carbon-containing material.

19. The semiconductor device of claim 14, wherein the offset mask layer comprises an oxide.

20. The semiconductor device of claim 14, wherein the offset mask layer is less than about 10 nm in thickness.
